(19) United States
(12) Patent Application Publication
(10) Pub. No.: US 2020/0381456 A1
(43) Pub. Date: Dec. 3, 2020

(54) ARRAY SUBSTRATE AND METHOD FOR MANUFACTURING THE SAME, DISPLAY DEVICE

(71) Applicants: Fuzhou BOE Optoelectronics Technology Co., Ltd., Fuzhou (CN); BOE TECHNOLOGY GROUP CO., LTD., Beijing (CN)

(72) Inventors: Zhongxing Ou, Beijing (CN); Shanshan Yang, Beijing (CN)

(21) Appl. No.: 16/628,574

(22) PCT Filed: May 31, 2019
(86) PCT No.: PCT/CN2019/089554

§ 371 Date: Jan. 3, 2020

(30) Foreign Application Priority Data
Jul. 27, 2018 (CN) 201810844542.5

(51) Int. Cl. H01L 27/12; G02F 1/1362

(52) U.S. Cl. CPC H01L 27/124; G02F 1/136209; H01L 27/1288

(57) ABSTRACT

An array substrate is provided which includes a base substrate, a plurality of gate line groups disposed on the base substrate, and a plurality of pixel units arranged in an array, each gate line group being disposed between two adjacent rows of pixel units, each gate line group includes a first gate line and a second gate line insulated from each other, the first gate line is connected to a control electrode of the first transistor, the second gate line is connected to a control electrode of the second transistor, and the control electrode of the first transistor and the control electrode of the second transistor are disposed in different layers. A method for manufacturing the array substrate and a display device are also provided.

### CROSS-REFERENCE TO RELATED APPLICATION

This application is a Section 371 National Stage application of International Application No. PCT/CN2019/089554, filed on May 31, 2019, which has not yet published, and claims priority to Chinese Patent Application No. 201810844542.5 filed on Jul. 27, 2018 in the State Intellectual Property Office of China, the disclosures of which are incorporated herein by reference.

### TECHNICAL FIELD

The present disclosure relates generally to a display technical field, and in particular, to an array substrate, a display device comprising the same and a method for manufacturing the array substrate.

### BACKGROUND

With the continuous development of display technology, a dual gate technology has received extensive attention as a technology that can significantly reduce the cost of products. In the dual gate technology, by optimizing a layout of the gate lines, the data lines, as well as the source driving integrated circuits and gate driving integrated circuits connected thereto, the cost of the display panel can be reduced in general.

### SUMMARY

According to an aspect of the present disclosure, there is provided an array substrate comprising a base substrate, a plurality of gate line groups disposed on the base substrate, and a plurality of pixel units arranged in an array, each gate line group being disposed between two adjacent rows of pixel units, wherein each gate line group comprises a first gate line and a second gate line insulated from each other, the first gate line is connected to a control electrode of the first transistor, the second gate line is connected to a control electrode of the second transistor, and the control electrode of the first transistor and the control electrode of the second transistor are disposed in different layers.

In an embodiment, the first gate line is disposed in a same layer with the control electrode of the first transistor, and the second gate line is disposed in a same layer with the control electrode of the second transistor.

In an embodiment, the control electrode of the second transistor is closer to the base substrate than the control electrode of the first transistor.

In an embodiment, the array substrate further comprises a plurality of data lines crossing the plurality of gate line groups, wherein the first transistor and the second transistor which are located adjacent to each other are respectively located on either side of one data line and the one data line is connected to a first electrode of the first transistor and a first electrode of the second transistor respectively.

In an embodiment, the first transistor comprises a first insulating layer, a semiconductor layer, a source/drain electrode layer, a second insulating layer and a first gate layer, which are sequentially disposed on the base substrate, and the second transistor comprises a second gate layer, the first insulating layer, the semiconductor layer, the source/drain electrode layer and the second insulating layer, which are sequentially disposed on the base substrate.

In an embodiment, the first transistor further comprises a first light shielding layer disposed between the base substrate and the first insulating layer, an orthographic projection of the first light shielding layer on the base substrate at least partially overlaps an orthographic projection of an active region of the first transistor on the base substrate.

In an embodiment, the second transistor further comprises a second light shielding layer disposed between the base substrate and the second gate layer, an orthographic projection of the second light shielding layer on the base substrate at least partially overlaps an orthographic projection of an active region of the second transistor on the base substrate.

In an embodiment, the first light shielding layer and the second light shielding layer are disposed in a same layer.

In an embodiment, the array substrate further comprises a conductive material layer respectively disposed between the first light shielding layer and the base substrate and between the second light shielding layer and the base substrate.

In an embodiment, the array substrate further comprises a first electrode layer, an insulating material layer and a second electrode layer, which are sequentially disposed on the base substrate, wherein the first electrode layer is disposed in a same layer with the conductive material layer, and the insulating material layer is disposed in a same layer with the first insulating layer. According to another aspect of the present disclosure, there is provided a display device comprising the above array substrate.

According to yet another aspect of the present disclosure, there is provided a method for manufacturing the above array substrate, the first transistor comprises a first insulating layer, a semiconductor layer, a source/drain electrode layer, a second insulating layer, and a first gate layer which are sequentially disposed on the base substrate, and the second transistor comprises a second gate layer, the first insulating layer, the semiconductor layer, the source/drain electrode layer and the second insulating layer, which are sequentially disposed on the base substrate, and the method comprises: sequentially forming the second gate layer, the first insulating layer, the semiconductor layer, the source/drain electrode layer, the second insulating layer and the first gate layer on the base substrate.

In an embodiment, the first transistor further comprises a first light shielding layer disposed between the base substrate and the first insulating layer, and the second transistor further comprises a second light shielding layer disposed between the base substrate and the second gate layer, the method further comprises: forming the first light shielding layer and the second light shielding layer in a same layer and with a same material by a same patterning process between the base substrate and the first insulating layer, wherein an orthographic projection of the first light shielding layer on the base substrate at least partially overlaps an orthographic projection of an active region of the first transistor on the base substrate and an orthographic projection of the second light shielding layer on the base substrate at least partially overlaps an orthographic projection of an active region of the second transistor on the base substrate.

In an embodiment, wherein the array substrate further comprises a conductive material layer respectively disposed between the first light shielding layer and the base substrate and between the second light shielding layer and the base substrate, the method further comprises: forming a conductive material layer between the first light shielding layer and the base substrate and between the second light shielding layer and the base substrate; wherein forming the conductive material layer, the first light shielding layer and the second light shielding layer in a same patterning process with a half tone photolithography mask.

In an embodiment, the array substrate further comprises a first electrode layer, an insulating material layer and a second electrode layer, which are sequentially disposed on the base substrate, the method further comprises forming a first electrode layer on the base substrate, sequentially forming the insulating material layer and the second electrode layer on the first electrode layer, wherein forming the first electrode layer, the conductive material layer, the first light shielding layer and the second light shielding layer in a same patterning process with a half tone photolithography mask, and forming the second electrode layer and the first gate layer in a same patterning process with a half tone photolithography mask.

In an embodiment, the first transistor has a top gate structure, and the second transistor has a bottom gate structure.

In an embodiment, the array substrate further comprises a plurality of data lines crossing the plurality of gate line groups, wherein the first transistor and the second transistor which are located adjacent to each other are respectively located on either side of one data line and the one data line is connected to a first electrode of the first transistor or a first electrode of the second transistor respectively.

### BRIEF DESCRIPTION OF THE DRAWINGS

In order to more clearly illustrate the technical solutions in the embodiments of the present disclosure, the accompanying drawings in the description of the embodiments of the present invention will be briefly described. Apparently, the drawings in the following description are only some embodiments of the present disclosure.

FIG. 1 schematically illustrates a partial top view of an array substrate according to an embodiment of the present disclosure.

FIG. 2 schematically illustrates a partial sectional view of an array substrate according to an embodiment of the present disclosure which is cut along a line AA in FIG. 1.

FIG. 3(a)-3(f) schematically illustrate respective steps of a method for manufacturing a light shielding layer and a first electrode layer of an array substrate according to an embodiment of the present disclosure.

The embodiments of the present disclosure have been illustrated by the above-described drawings, which will be described in more detail later. The drawings and the literal description are not intended to limit the scope of the present invention in any way, but the concept of the present disclosure will be described for those skilled in the art by reference to the specific embodiments.

### DETAILED DESCRIPTION OF EMBODIMENTS

The technical solutions of the embodiments of the present disclosure will be further described in detail below with reference to the accompanying drawings in order to make the objectives, technical solutions and advantages of the embodiments of the present disclosure more clear.

In one of the dual gate technologies, the gate lines are wired in a manner of parallel wiring in a same layer. In order to avoid electrical shorts between two parallel gate lines arranged in the same layer, usually it is necessary to provide a spacing of at least 6.5 μm between the two parallel gate lines. However, the spacing between the two parallel gate lines as well as the width of the two gate lines occupy a relative large area, so that the shielding area of a metal of the display device is large, while the effective pixel area is small, thereby reducing an aperture ratio and transmittance of the display device. Moreover, even if a sufficient spacing is provided between the two parallel gate lines, an electrical shorting between the two parallel gate lines cannot be completely avoided.

However, in the dual gate technology of wiring the gate lines in a manner of parallel wiring in a same layer, provisions on widths of the two parallel gate lines and the spacing between the gate lines can hardly meet the requirement for preventing a short circuit of the electrical appliance as well as a relative high aperture ratio and transmission.

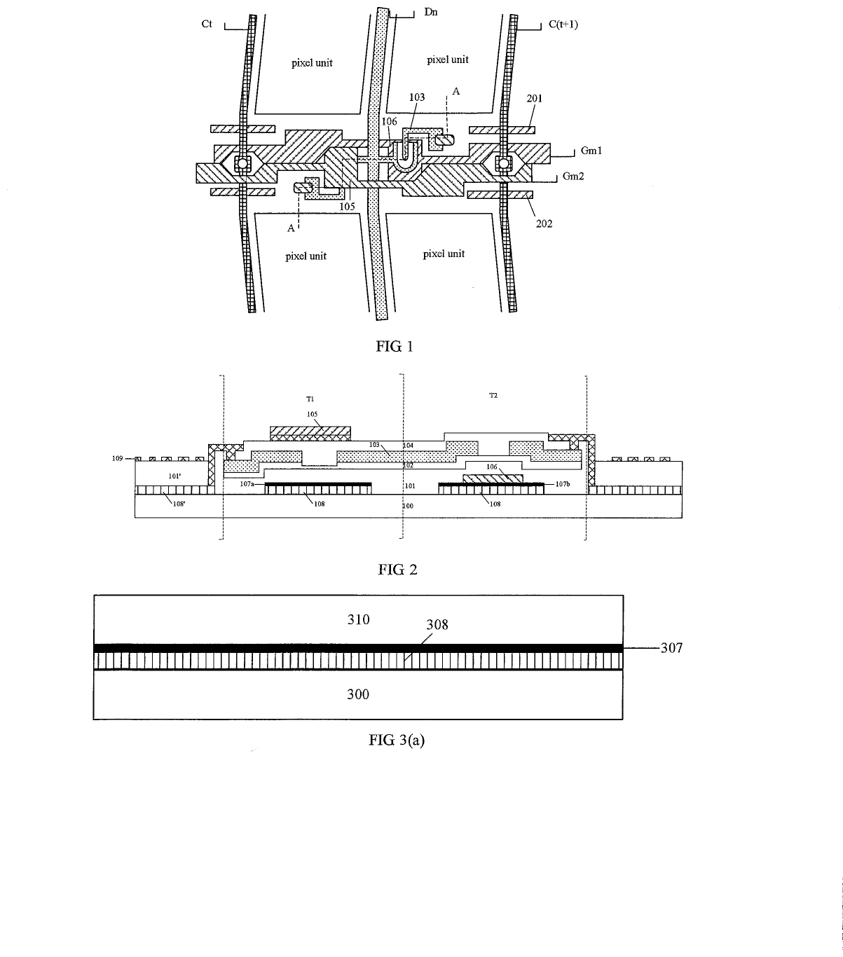

In view of this, the present disclosure provides an improved array substrate. FIG. 1 schematically illustrates a partial top view of an array substrate according to an embodiment of the present disclosure, and FIG. 2 schematically illustrates a partial sectional view of an array substrate according to an embodiment of the present disclosure which is cut along a line AA in FIG. 1. As shown in FIGS. 1 and 2, the array substrate includes a base substrate 100, a plurality of gate line groups (Gm1, Gm2) disposed on the base substrate 100, a plurality of data lines Dn, and a plurality of common electrode lines Ct, C(t+1), and a plurality of pixel units arranged in an array. Each gate line group is disposed between two adjacent rows of pixel units. Each gate line group includes a first gate line Gm1 and a second gate line Gm2 which are insulated from each other. The first gate line Gm1 is connected to a control electrode of a first transistor T1, the second gate line Gm2 is connected to a control electrode of a second transistor T2. The control electrode of the first transistor T1 and the control electrode of the second transistor T2 are disposed in different layers. The extending direction of the data line Dn crosses the first gate line Gm1 and the second gate line Gm2, and the data line Dn is respectively connected to a first electrode of the first transistor T1 and a first electrode of the second transistor T2, which transistors T1 and T2 are located on either side of the data line Dn and adjacent to the data line Dn.

As shown in FIG. 1, at a position where the common electrode lines Ct, C (t+1) and the gate line group Gm1, Gm2 intersect, in particular on either side of the gate line group, two crossbars 201, 202 which are substantially parallel to the gate line group are provided. These two crossbars are used as a barrier wall to prevent a spacer from sliding. The connection manner of the pixel unit belongs to the related art, which is not repeated here.

According to an exemplary embodiment, in particular, the first gate line Gm1 is disposed in a same layer as the control electrode of the first transistor T1, and the second gate line Gm2 is disposed in the same layer as the control electrode of the second transistor T2.

In the array substrate according to an embodiment of the present disclosure, the control electrode of the first transistor T1 and the control electrode of the second transistor T2 are disposed in different layers, and the first gate line Gm1 and the second gate line Gm2 in each gate line group are correspondingly are disposed in different layers, in this way, the requirements to the spacing between the first gate line Gm1 and the second gate line Gm2 can be eliminated in the case where the first gate line Gm1 and the second gate line Gm2 are disposed in the same layer. Therefore, the shielding area of a metal of the display device including the array substrate is reduced, the effective pixel area is increased, and thereby increasing the aperture ratio and transmittance of the display device. Moreover, since the first gate line Gm1 and the second gate line Gm2 are disposed in different layers, the problem of electrical short between the two parallel gate lines can be fundamentally solved.

It should be noted that, although only one gate line group and one data line are schematically illustrated in FIG. 1, this is only a part of the array substrate provided by the embodiment of the present disclosure. Those skilled in the art will appreciate that, the array substrate may include, according to actual needs, any number of gate line groups whose extension directions are parallel to each other and any number of data lines whose extension directions are parallel to each other, and the extension direction of the gate line groups and the extension direction of the data lines may be perpendicular to each other.

It should also be noted that, although in the embodiment shown in FIG. 1, the data line Dn is respectively connected to the first electrode of the first transistor T1 and the first electrode of the second transistor T2, which transistors T1 and T2 are located on either side of the data line Dn and are adjacent to the data line Dn. The concept of the present disclosure is not limited to this. In an alternative embodiment, each data line may be connected only to the first electrode of the transistor on one side thereof. Those skilled in the art will appreciate that the concepts of the present disclosure may be equally applicable to other array substrates having a dual gate structure.

In an exemplary embodiment, as shown in FIG. 2, the control electrode of the second transistor T2 is closer to the base substrate than the control electrode of the first transistor T1. For example, the first transistor T1 may have a top gate structure while the second transistor T2 may have a bottom gate structure. Typically, the transistor has a bottom gate structure if the gate of the transistor is closer to the base substrate than the active layer of the transistor. Conversely, the transistor has a top gate structure if the gate of the transistor is further away from the base substrate than the active layer of the transistor.

In an exemplary embodiment, as shown in FIG. 2, the first transistor T1 includes a first insulating layer 101, a semiconductor layer 102, a source/drain electrode layer 103, a second insulating layer 104 and a first gate layer 105, which are sequentially disposed on a base substrate 100. The second transistor T2 includes a second gate layer 106, the first insulating layer 101, the semiconductor layer 102, the source/drain electrode layer 103, and the second insulating layer 104, which are sequentially disposed on the base substrate 100. That is, the first insulating layer 101 of the first transistor T1 and the second transistor T2 may be simultaneously formed, and the semiconductor layer 102 of the first transistor T1 and the second transistor T2 may be simultaneously formed, the source/drain electrode layer 103 of the first transistor T1 and the second transistor T2 may be simultaneously formed, and the second insulating layer 104 of the first transistor T1 and the second transistor T2 may be simultaneously formed.

Optionally, the first transistor T1 further includes a first light shielding layer 107a disposed between the base substrate 100 and the first insulating layer 101. An orthographic projection of the first light shielding layer 107a on the base substrate 100 at least partially overlaps with an orthographic projection of an active region of the first transistor T1 on the base substrate 100. Optionally, the orthographic projection of the first light shielding layer 107a on the base substrate 100 at least partially overlaps with an orthographic projection of a region between a source electrode and a drain electrode of the first transistor T1 on the base substrate 100. Optionally, the orthographic projection of the first light shielding layer 107a on the base substrate 100 completely overlaps with the orthographic projection of the active region of the first transistor T1 on the base substrate 100. When an array substrate according to an embodiment of the present disclosure is used in a display device including a backlight, such as a liquid crystal display, light emitted by the backlight disposed under the base substrate 100 may adversely affect the electrical performance of the active region of the transistor. By providing the first light shielding layer 107a between the base substrate 100 and the first insulating layer 101, and causing the orthographic projection of the first light shielding layer 107a on the base substrate 100 to at least partially overlap the orthographic projection of the active region of the first transistor T1 on the base substrate 100, the adverse effects of the light emitted by the backlight on the active region of the first transistor T1 may be eliminated, thereby ensuring the performance of the first transistor T1.

According to some exemplary embodiments of the present disclosure, the second transistor T2 further includes a second light shielding layer 107b disposed between the base substrate 100 and the second gate layer 106. An orthographic projection of the second light shielding layer 170b on the base substrate 100 at least partially overlaps an orthographic projection of an active region of the second transistor T2 on the base substrate 100. Optionally, the orthographic projection of the second light shielding layer 170b on the base substrate 100 at least partially overlaps with an orthographic projection of a region between a source electrode and a drain electrode of the second transistor T2 on the base substrate 100. Optionally, the orthographic projection of the second light shielding layer 170b on the base substrate 100 completely overlaps with the orthographic projection of the active region of the second transistor T2 on the base substrate 100. When an array substrate according to an embodiment of the present disclosure is used in a display device including a backlight such as a liquid crystal display, light emitted by the backlight disposed under the base substrate 100 may adversely affect the electrical performance of an active region of the transistor. By providing the second light shielding layer 107b between the base substrate 100 and the second gate layer 106, and causing the orthographic projection of the second light shielding layer 107b on the base substrate 100 to at least partially overlap the orthographic projection of the active region of the second transistor T2 on the base substrate 100, the adverse effect of the light emitted by the backlight on the active region of the second transistor T2 may be eliminated, thereby ensuring the performance of the second transistor T2.

In an exemplary embodiment, the first light shielding layer 107a and the second light shielding layer 107b are disposed in a same layer. That is to say, the first light shielding layer 107a and the second light shielding layer 107b may be simultaneously formed in a same patterning process, thereby simplifying the fabrication process of the array substrate and reducing the manufacturing cost.

Further, as shown in FIG. 2, the array substrate may further include a conductive material layer 108 disposed between the first light shielding layer 107a and the second light shielding layer 107b with the base substrate 100.

In an exemplary embodiment, the array substrate further includes a first electrode layer 108′, an insulating material layer 101′ and a second electrode layer 109, which are sequentially disposed on the base substrate 100. The first electrode layer 108′ is disposed in the same layer as the conductive material layer 108, and the insulating material layer 101′ is disposed in the same layer as the first insulating layer 101. That is to say, in the exemplary embodiment, the first electrode layer 108′ and the conductive material layer 108 may be simultaneously formed in the same patterning process, and the insulating material layer 101′ may be patterned in the same manner as the first insulating layer 101.

Embodiments of the present disclosure also provide a method for manufacturing any of the above array substrates. The method includes: the first transistor includes a first insulating layer, a semiconductor layer, a source/drain electrode layer, a second insulating layer, and a first gate layer, which are sequentially disposed on the base substrate, and the second transistor includes a second gate layer, the first insulating layer, the semiconductor layer, the source/drain electrode layer and a second insulating layer, which are sequentially disposed on the base substrate, and the method includes: sequentially forming the second gate layer, the first insulating layer, the semiconductor layer, the source/drain electrode layer, the second insulating layer, and the first gate layer on the base substrate.

As used herein, “a half tone photolithographic mask” refers to a photolithographic mask having different amounts of light transmitted at different locations on the photolithographic mask, such that exposure amounts at different locations on a photoresist illuminated through the photolithographic mask are different, some portions of the photoresist are completely exposed, some portions are partially exposed, and other portions are not exposed, thereby forming a pattern of photoresist having a non-uniform thickness after development. Taking positive photoresist as an example, the fully exposed photoresist is completely removed after development, and the partially exposed photoresist is partially removed (i.e., thinned) after development, and the photoresist without being exposed doesn't change after development. Here, “partial exposure” generally means exposure of light transmission amount of 30%, 40%, 50% or 60%.

In the array substrate manufactured by the above-described method, by disposing the control electrode of the first transistor and the control electrode of the second transistor in different layers, and correspondingly disposing the first gate line and the second gate line in each gate line group in different layers, the requirement to the spacing between the first gate line and the second gate line may be eliminated in the case where the first gate line and the second gate line are disposed in the same layer. Therefore, a shielding area of a metal of the display device including the array substrate is reduced, the effective pixel area is increased, and thereby increasing the aperture ratio and transmittance of the display device. Moreover, since the first gate line and the second gate line are disposed in different layers, the problem of electrical short between the two parallel gate lines can be fundamentally solved.

In an exemplary embodiment, the above method further includes forming a first light shielding layer and a second light shielding layer in a same layer and with a same material by a same patterning process between the base substrate and the first insulating layer. Such that an orthographic projection of the first light shielding layer on the base substrate at least partially overlaps an orthographic projection of an active region of the first transistor on the base substrate and an orthographic projection of the second light shielding layer on the base substrate at least partially overlaps an orthographic projection of an active region of the second transistor on the base substrate.

In an exemplary embodiment, the above method further includes: forming a conductive material layer between the first light shielding layer and the second light shielding layer with the base substrate; and forming a first electrode layer on the base substrate. In particular, the first electrode layer, the conductive material layer, the first light shielding layer and the second light shielding layer are formed in a same patterning process with a half tone photolithography mask.

In an exemplary embodiment, the above method further includes sequentially forming an insulating material layer and a second electrode layer on the first electrode layer. In particular, the second electrode layer and the first gate layer are formed in a same patterning process with a half tone photolithography mask.

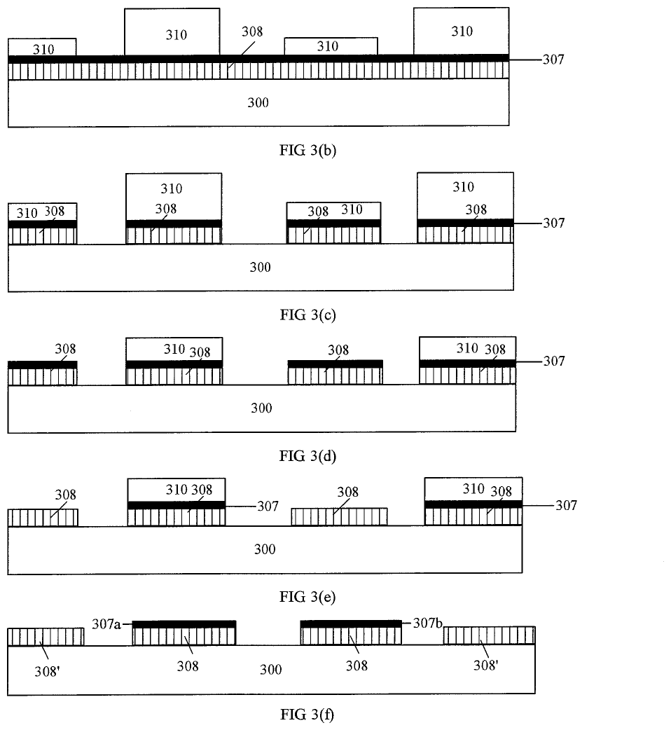

A method for manufacturing an array substrate according to an embodiment of the present disclosure will be specifically described below with reference to FIGS. 2 and 3(a)-3(f).

Firstly, as shown in FIG. 3(a), a conductive material layer 308 and a light shielding material layer 307 are sequentially deposited on the base substrate 300, and a photoresist 310 is applied on the light shielding material layer 307.

Next, as shown in FIG. 3(b), the photoresist 310 is exposed and developed with a half tone photolithography mask to form a photoresist pattern having a different thickness.

Then, as shown in FIG. 3(c), the conductive material layer 308 and the light shielding material layer 307 are etched by using the photoresist pattern as a mask to remove the conductive material and the light shielding material in a region where is not covered with the photoresist pattern.

Then, as shown in FIG. 3(d), the photoresist pattern is subjected to an ashing process to remove a thinner portion of the photoresist pattern and to thin a thicker portion of the photoresist pattern.

Next, as shown in FIG. 3(e), the conductive material layer 308 and the light shielding material layer 307 are further etched by using the photoresist pattern as a mask to remove the light shielding material in a region where is not covered with the photoresist pattern.

Then, as shown in FIG. 3(f), the remaining photoresist is removed to form a first electrode layer 308′, a conductive material layer 308, a first light shielding layer 307a, and a second light shielding layer 307b.

In the process shown in FIGS. 3(a)-3(f), the first electrode layer 308′, the conductive material layer 308, the first light shielding layer 307a, and the second light shielding layer 307b can be simultaneously formed using only one mask. Therefore, the manufacturing cost of the array substrate may be significantly reduced.

Thereafter, a bottom gate metal material is deposited on the structure as shown in FIG. 3(f), and the bottom gate metal material is patterned to form the second gate 106 of the second transistor T2. Thereafter, a first insulating layer 101, a semiconductor layer 102, a source/drain electrode layer 103, and a second insulating layer 104 are sequentially formed over the second gate 106, and via holes are formed in the second insulating layer 104 to electrically connect the source/drain electrodes layer 103.

Finally, the second electrode layer 109 and the control electrode of the first transistor T1 (made by the first gate layer 105) can be simultaneously formed by a process similar to that of FIGS. 3(a)-3(f) using one same half tone photolithography mask, so as to significantly reduce the manufacturing cost of the array substrate.

In addition, embodiments of the present disclosure also provide a display device including any of the above array substrates.

In the display device according to an embodiment of the present disclosure, by disposing the control electrode of the first transistor and the control electrode of the second transistor in different layers, and correspondingly disposing the first gate line and the second gate line in each gate line group in different layers, the requirement to the spacing between the first gate line and the second gate line may be eliminated in the case where the first gate line and the second gate line are disposed in the same layer. Therefore, a shielding area of a metal of the display device including the array substrate is reduced, the effective pixel area is increased, and thereby increasing the aperture ratio and transmittance of the display device. Moreover, since the first gate line and the second gate line are disposed in different layers, the problem of electrical short between the two parallel gate lines can be fundamentally solved.

The concepts of the present disclosure can be widely applied to various electronic systems having display functions such as mobile phones, notebook computers, and liquid crystal televisions.

Unless otherwise defined, technical terms or scientific terms used in the present disclosure are intended to be understood in an ordinary meaning. The words “first”, “second” and similar terms used in the present disclosure do not denote any order, quantities or importance, but are used to distinguish different components. Similarly, the words “a”, “an”, “the” and the like do not indicate a limit on quantity, but rather indicate that there is at least one. The words “comprising”, “including” and the like mean that the element or item appearing before the word encompasses the element or item appearing after the word and its equivalent without excluding other elements or items. The words “connected”, “connecting” and the like are not limited to physical or mechanical connections, but may include electrical connections, whether direct or indirect. The term “upper”, “lower”, “left”, “right” and the like are only used to indicate the relative positional relationship, and when the absolute position of the object to be described is changed, the relative positional relationship may also be changed accordingly. It should be noted that the features in the above embodiments may be used in any combination without conflict.

The above description is only a specific embodiment of the present disclosure, but the protective scope of the present disclosure is not limited thereto, and any change or replacement that can be readily conceived by those skilled in the art within the technical scope of the present disclosure should be intended to be covered by the protective scope of the present disclosure. Therefore, the protective scope of the present disclosure should be determined by the scope of the claims.

1. An array substrate comprising a base substrate, a plurality of gate line groups disposed on the base substrate, and a plurality of pixel units arranged in an array, each gate line group being disposed between two adjacent rows of pixel units, wherein
each gate line group comprises a first gate line and a second gate line insulated from each other,
the first gate line is connected to a control electrode of the first transistor,
the second gate line is connected to a control electrode of the second transistor, and
the control electrode of the first transistor and the control electrode of the second transistor are disposed in different layers.

2. The array substrate according to claim 1, wherein the first gate line is disposed in a same layer with the control electrode of the first transistor, and the second gate line is disposed in a same layer with the control electrode of the second transistor.

3. The array substrate according to claim 1, wherein the control electrode of the second transistor is closer to the base substrate than the control electrode of the first transistor.

4. The array substrate according to claim 1, further comprising a plurality of data lines crossing the plurality of gate line groups, wherein the first transistor and the second transistor which are located adjacent to each other are respectively located on either side of one data line and the one data line is connected to a first electrode of the first transistor and a first electrode of the second transistor respectively.

5. The array substrate according to claim 1, wherein the first transistor comprises a first insulating layer, a semiconductor layer, a source/drain electrode layer, a second insulating layer and a first gate layer, which are sequentially disposed on the base substrate, and the second transistor comprises a second gate layer, the first insulating layer, the semiconductor layer, the source/drain electrode layer and the second insulating layer, which are sequentially disposed on the base substrate.

6. The array substrate according to claim 5, wherein the first transistor further comprises a first light shielding layer disposed between the base substrate and the first insulating layer, an orthographic projection of the first light shielding layer on the base substrate at least partially overlaps an orthographic projection of an active region of the first transistor on the base substrate.

7. The array substrate according to claim 5, wherein the second transistor further comprises a second light shielding layer disposed between the base substrate and the second gate layer, an orthographic projection of the second light shielding layer on the base substrate at least partially overlaps an orthographic projection of an active region of the second transistor on the base substrate.

8. The array substrate according to claim 7, wherein the first light shielding layer and the second light shielding layer are disposed in a same layer.

9. The array substrate according to claim 7, further comprising a conductive material layer respectively disposed between the first light shielding layer and the base substrate and between the second light shielding layer and the base substrate.

10. The array substrate according to claim 9, further comprising a first electrode layer, an insulating material layer and a second electrode layer, which are sequentially disposed on the base substrate, wherein the first electrode layer is disposed in a same layer with the conductive material layer, and the insulating material layer is disposed in a same layer with the first insulating layer.

11. A display device comprising the array substrate according to claim 1.

12. A method for manufacturing the array substrate according to claim 1, wherein the first transistor comprises a first insulating layer, a semiconductor layer, a source/drain electrode layer, a second insulating layer, and a first gate layer which are sequentially disposed on the base substrate, and the second transistor comprises a second gate layer, the first insulating layer, the semiconductor layer, the source/drain electrode layer and the second insulating layer, which are sequentially disposed on the base substrate, and wherein
the method comprises:
sequentially forming the second gate layer, the first insulating layer, the semiconductor layer, the source/drain electrode layer, the second insulating layer and the first gate layer on the base substrate.

13. The method according to claim 12, wherein the first transistor further comprises a first light shielding layer disposed between the base substrate and the first insulating layer, and the second transistor further comprises a second light shielding layer disposed between the base substrate and the second gate layer, the method further comprises:
forming the first light shielding layer and the second light shielding layer in a same layer and with a same material by a same patterning process between the base substrate and the first insulating layer, wherein an orthographic projection of the first light shielding layer on the base substrate at least partially overlaps an orthographic projection of an active region of the first transistor on the base substrate and an orthographic projection of the second light shielding layer on the base substrate at least partially overlaps an orthographic projection of an active region of the second transistor on the base substrate.

14. The method according to claim 13, wherein the array substrate further comprises a conductive material layer respectively disposed between the first light shielding layer and the base substrate and between the second light shielding layer and the base substrate, the method further comprises:
forming a conductive material layer between the first light shielding layer and the base substrate and between the second light shielding layer and the base substrate;
wherein forming the conductive material layer, the first light shielding layer and the second light shielding layer in a same patterning process with a half tone photolithography mask.

15. The method according to claim 14, wherein the array substrate further comprises a first electrode layer, an insulating material layer and a second electrode layer, which are sequentially disposed on the base substrate,
the method further comprises:
sequentially forming the insulating material layer and the second electrode layer on the first electrode layer,
wherein forming the first electrode layer, the conductive material layer, the first light shielding layer and the second light shielding layer in a same patterning process with a half tone photolithography mask, and
forming the second electrode layer and the first gate layer in a same patterning process with a half tone photolithography mask.

16. The array substrate according to claim 3, wherein the first transistor has a top gate structure, and the second transistor has a bottom gate structure.

17. The array substrate according to claim 1, further comprising a plurality of data lines crossing the plurality of gate line groups, wherein the first transistor and the second transistor which are located adjacent to each other are respectively located on either side of one data line and the one data line is connected to a first electrode of the first transistor or a first electrode of the second transistor respectively.
